(19) United States
(12) Patent Application Publication
(10) Pub. No.: US 2025/0143038 A1
(43) Pub. Date: May 1, 2025

(54) OPTOELECTRONIC PACKAGE AND METHOD

(71) Applicant: ams-OSRAM International GmbH, Regensburg (DE)

(72) Inventors: Daniel Richter, Abbach (DE); Gunnar Petersen, Regensburg (DE); Andreas Reith, Steinach (DE)

(21) Appl. No.: 18/834,590

(22) PCT Filed: Jan. 27, 2023
(86) PCT No.: PCT/EP2023/052083

§ 371 Date: Jul. 30, 2024

(30) Foreign Application Priority Data
Feb. 2, 2022 (DE) 10 2022 102 494.6

(51) Int. Cl. H10H 20/854; H10H 20/01; H10H 20/855; H10H 20/857; H10H 29/24

(52) U.S. Cl. CPC H10H 20/854; H10H 20/0362; H10H 20/0364; H10H 20/857; H10H 20/855; H10H 29/24

(57) ABSTRACT

In an embodiment an optoelectronic package includes a carrier substrate having at least two through vias filled with an electrically conductive material, at least one optoelectronic component arranged on the carrier substrate, wherein the at least one optoelectronic component is configured to generate light in an ultraviolet range, and wherein the at least one optoelectronic component has at least two connection regions, each of which is electrically coupled to one of the two electrically conductive vias and a package material surrounding the at least one optoelectronic component, wherein the package material is based on a fluoropolymer and covers side surfaces of the at least one optoelectronic component at least in regions, and wherein a top surface of the at least one optoelectronic component opposite the connection regions remains free of the package material.

### CROSS-REFERENCE TO RELATED APPLICATIONS

This patent application is a national phase filing under section 371 of PCT/EP2023/052083, filed Jan. 27, 2023, which claims the priority of German patent application 10 2022 102 494.6, filed Feb. 2, 2022, each of which is incorporated herein by reference in its entirety.

### TECHNICAL FIELD

The present invention relates to an optoelectronic package and a method for manufacturing an optoelectronic package.

### BACKGROUND

Optoelectronic components that generate light in an ultraviolet part of the electromagnetic spectrum, so-called UVC components, are confronted with the challenge of achieving the required brightness with a sufficient service life.

Currently, packages for generating ultraviolet light are often realized on a ceramic substrate. For this purpose, the optoelectronic component is mounted in a multilayer ceramic with a cavity, whereby the side walls are usually designed vertically. To protect the optoelectronic component, there is often an additional glass cover, which is transparent for the ultraviolet part of the spectrum.

The disadvantage of this concept is that a significant proportion of the light is absorbed by the cavity, which reduces the optical performance of the overall package. This is mainly due to the fact that the optoelectronic components are not designed as surface emitters but as volume emitters and therefore emit light to all sides. Alternatively, it is therefore possible to introduce an additional lens material into the cavity in order to deflect the light emitted by the component, collimate it and emit it in a desired direction.

### SUMMARY

Embodiments provide components for generating light in an ultraviolet part of the electromagnetic spectrum more efficient without making the design and manufacture more technically complex and therefore more expensive.

The inventors propose providing a package which is based on a fluoropolymer-based housing material. Fluorotetrapolyethylene or polychlorotrifluoroethylene is a particularly suitable housing material for this purpose. On the one hand, this material has the property of withstanding the high-energy ultraviolet radiation of the optoelectronic component without major damage, which significantly increases the service life of such a package. On the other hand, a fluoropolymer comprises a high reflectivity for this spectral range, so that light emitted by side surfaces of an optoelectronic component arranged in the package is reflected back. As a result, a corresponding radiation in the direction of the emission plane can be achieved and the optical performance of the package can be significantly improved compared to conventional arrangements.

The basic idea is thus a combination of special materials and processes for manufacturing a package and in particular a QFN package, in which a QFN package with high effectiveness in the UVC range and a long service life is realized by the special design of the housing material and the use of the suitable material. A suitable process sequence during the manufacture of such a package allows high-temperature steps, which can lead to possible damage to the optoelectronic component, to be carried out before the component is assembled.

In one aspect, an optoelectronic package comprises a carrier substrate with at least two vias through the carrier substrate filled with an electrically conductive material, in particular a metal, for making electrical contact with an optoelectronic component. In addition, the optoelectronic package comprises at least one optoelectronic component which is arranged on the carrier substrate and is configured to generate light in an ultraviolet range of the spectrum, the at least one optoelectronic component having at least two connection regions, each of which is electrically coupled to one of the two electrically conductive vias. The at least one optoelectronic component is furthermore surrounded by a package material based on a fluoropolymer, which covers side surfaces of the at least one optoelectronic component at least in some areas, wherein a top surface of the at least one optoelectronic component opposite the connection regions of the at least one optoelectronic component remains free of the package material. The package material based on a fluoropolymer can in particular comprise tetrafluoropolyethylene and/or polychlorotrifluoroethylene. Both materials belong to the polyhaloolefins, which are characterized by a high chemical inertness and at the same time a high stability against light in the UVC range of the spectrum.

According to the proposed principle, the package material based on the fluoropolymer at least partially surrounds the at least one optoelectronic component, in particular at least side surfaces of the at least one optoelectronic component, whereby a top surface of the at least one optoelectronic component opposite the connection regions of the at least one optoelectronic component is recessed. The connection regions are also free of the package material.

In this way, an embedding of the at least one optoelectronic component is created by means of a highly reflective material, which deflects the light generated by the at least one optoelectronic component in the direction of the top surface or light exit side.

In some aspects, it is provided that the top surface of the at least one optoelectronic component is substantially flush with a top surface of the package material. In other words, in this embodiment example, a top surface of the package material is substantially at the same height as the top surface and thus the light emitting side of the optoelectronic component.

If the top surface of the at least one optoelectronic component has to be particularly protected, it may be expedient in some aspects to arrange it below the top surface of the package material so that the component is completely present within a recess in the package material.

The top surface may be filled with an additional transparent material for further protection against possible damage but also for light collimation. In some aspects, a transparent material is arranged on the top surface of the at least one optoelectronic component. This may, for example, be a lens material which forms an optical element, such as a lens, over the light emission side for further shaping the light emitted by the component.

Some aspects deal with the package material based on a fluoropolymer. In some aspects, this fluoropolymer consists essentially of polytetrafluoroethylene. Alternatively, individual fluorine components in the polymer can also be replaced by chlorine or other halides. In addition to their resistance to high temperatures and chemicals, such polymers are also characterized by a non-existent melting point, i.e. they decompose instead of melting. For this reason, it is envisaged in some aspects that the optoelectronic package with the package material based on a fluoropolymer is sintered or produced by compression molding.

In some further embodiments, the package material is formed by a composite laminate layer. The package material can thereby comprise at least a first composite film and a first insulating layer based on a fluoropolymer, in particular comprising polytetrafluoroethylene (PTFE), which are arranged one above the other in the form of a layer stack. In particular, the package material can comprise a first composite film which is arranged between a first and a second insulating layer and which connects the two insulating layers to one another. In addition, the package material can comprise a second composite film, which is arranged on a top surface of the first or second insulating layer facing away from the first composite film and which is in contact with the carrier substrate. The composite films may, for example, be adhesive films, which may comprise at least one of CTFE and FEP.

At the time of manufacturing the optoelectronic package, the composite laminate layer may, for example, be a pre-structured composite laminate layer with at least one opening, which is arranged on the carrier substrate so that the optoelectronic component is arranged in the opening. The optoelectronic component is accordingly surrounded by the composite laminate layer, but at this point there may still be a gap between the optoelectronic component and the composite laminate layer to enable the optoelectronic component to be arranged in the at least one opening. By pressing the composite laminate layer with the carrier substrate, the material of the first or second composite film is pressed into gaps between the optoelectronic component and the first or second insulating layer, so that in the finished optoelectronic package the material of the first or second composite film of the package material covers the side surfaces of the optoelectronic component at least in some areas.

Further aspects deal with the different design possibilities of the carrier substrate. In some embodiments, the package comprises a layer based on a fluoropolymer with at least two vias filled with an electrically conductive material. The vias are arranged in the area of the optoelectronic component and comprise at least two flat contact areas on a side facing away from the optoelectronic component, by means of which the optoelectronic component can be supplied with electricity. An adhesive composite film can also be arranged between the carrier substrate and the package material. The package material or the optoelectronic component is applied to this composite film. In this context, the composite film can therefore be an adhesive film.

In some further embodiments, the carrier substrate comprises a first structured copper laminate layer and a second structured copper laminate layer with an insulating layer or an insulating core between the two structured copper laminate layers. The insulating core comprises at least two vias filled with an electrically conductive material, in particular a metal. The vias are located in the area of the optoelectronic component and are each electrically coupled to one of the two connection regions. Depending on the configuration, the insulating core also comprises a fluoropolymer, but may also consist of or comprise other materials, such as FR4 or a mixture of polytetrafluoroethylene and glass particles.

In some further embodiments, the carrier substrate comprises a stack of layers consisting of an insulating layer that is transparent to UV light and a layer that reflects UV light. The insulating layer that is transparent to UV light can be in contact with the package material or the optoelectronic component and serve as a non-conductive passivation layer (e.g. SiO₂, Al₂O₃) between other layers of the layer stack and the optoelectronic component (UVC LED chip). The layer reflecting UV light can, for example, be formed from an electrically conductive material. In particular, the layer reflecting UV light can be configured to reflect light in the UVC wavelength range particularly well. This can be realized by a metallic layer (e.g. Al, Ag) or a combination of metallic mirror and Bragg reflector (DBR stack). In addition, the carrier substrate or the layer stack can have a reinforcing layer, which is arranged, for example, between the insulating layer that is transparent to UV light and the layer that reflects UV light. The reinforcing layer can increase the mechanical stability of the carrier substrate.

The at least two vias through the carrier substrate filled with an electrically conductive material, in particular a metal, for electrical contacting of the optoelectronic component can also be protected by a passivation layer. The passivation layer can surround the vias in a lateral direction so that they are not in contact with the layer stack.

In some further embodiments, the carrier substrate comprises a multi-layer stack comprising at least a first composite film, a structured copper laminate layer and an insulating layer disposed between the first composite film and the structured copper laminate layer. In addition, the multi-layer stack can comprise a further insulating layer and a second composite film arranged between the two insulating layers. By means of such a multi-layer stack, it is possible, for example, to provide a complex substructure with, for example, several interconnection levels, e.g. for controlling several optoelectronic components. In addition, so-called “fan-out wafer-level packaging” is possible using such a multi-layer stack. The multi-layer stack can, for example, comprise PTFE multilayers and/or hybrid multilayers and/or can comprise or be formed from a prepreq with thermoplastic composite films. By means of a multi-layer stack, for example, a high degree of interconnection freedom can be achieved by stacking and possibly structuring passivation layers and conductor track layers, thus resulting in a large number of electrical paths through the multi-layer stack in combination with vias. For complex arrangements with, for example, a large number of optoelectronic components, several interconnection layers may be necessary to realize the desired wiring.

Depending on the embodiment, the insulating layer or layers may comprise a fluoropolymer (for example PTFE), but may also consist of or comprise other materials, such as FR4 or a mixture of polytetrafluoroethylene and glass particles. The first or second composite film can also be formed, for example, by a thermoplastic composite film, which can comprise at least one of CTFE and FEP.

A further aspect relates to a method for manufacturing at least one optoelectronic package. In principle, a distinction can be made between two different process flow variants.

According to a first embodiment, a composite of the at least one optoelectronic component surrounded by package material is produced in a first step, which is applied to the carrier substrate in a further step and bonded thereto. According to a second embodiment, on the other hand, the at least one optoelectronic component is surrounded on the carrier substrate by means of a prefabricated and prestructured layer of packaging material, which is pressed onto the carrier substrate.

The method according to the first embodiment comprises the steps of:
Providing a temporary carrier with at least one optoelectronic component arranged thereon, wherein the at least one optoelectronic component is configured to generate light in an ultraviolet range of the spectrum and comprises at least two connection regions which point in the direction of the temporary carrier;
Inserting the temporary carrier into a mold tool;
Surrounding the at least one optoelectronic component arranged on the temporary carrier with a package material based on a fluoropolymer, in particular polytetrafluoroethylene, in such a way that the side surfaces of the optoelectronic component are covered by the package material at least in some areas and a top surface of the at least one optoelectronic component opposite the connection regions remains free of the package material;
Removing the temporary carrier; and
Providing a carrier substrate with at least two vias filled with an electrically conductive material, in particular a metal, through the carrier substrate on a side of the package material opposite the top surface of the at least one optoelectronic component, each of the two electrically conductive vias being electrically coupled to a connection region.

The steps of providing the temporary carrier, inserting the temporary carrier into a mold tool, surrounding the at least one optoelectronic component arranged on the temporary carrier with a package material, and removing the temporary carrier can correspond to the creation of a composite of the at least one optoelectronic component surrounded by package material, which is applied to the carrier substrate and connected to it in a further step.

According to at least one embodiment, the step of surrounding the at least one optoelectronic component arranged on the temporary carrier with the package material comprises sintering or compression molding the package material. The mold tool can be configured for compression molding, for example. In addition, the step of surrounding the at least one optoelectronic component arranged on the temporary carrier with the package material can comprise removing package material from the top of the at least one optoelectronic component. This can be done, for example, by etching, grinding or polishing.

According to at least one embodiment, the step of surrounding the at least one optoelectronic component arranged on the temporary carrier with the package material comprises compression molding the package material into an intermediate space surrounding the at least one optoelectronic component arranged on the temporary carrier, and optionally sintering the package material located in the intermediate space in a temperature range below 450° C. and in particular below 400° and in particular below 350° C.

According to at least one embodiment, the method also comprises the step of pressing the carrier substrate with the package material and the at least one optoelectronic component. Alternatively, the carrier substrate can also be produced or grown by applying individual layers to the package material.

The carrier substrate can, for example, be formed by a multi-layer stack as described above.

According to at least one embodiment, the step of providing the carrier substrate comprises creating and filling the at least two vias after the carrier substrate has been provided or arranged on the side of the package material opposite the top surface of the at least one optoelectronic component. The vias can be etched or lasered into the carrier substrate and then filled with an electrically conductive material after the carrier substrate has been provided or arranged on the side of the package material opposite the top surface of the at least one optoelectronic component. The vias can already be prepared for this purpose and merely filled with an intermediate material such as a photoresist, or they can first be introduced into the carrier substrate on the package material. Alternatively, it is possible that the vias are already present in the carrier substrate before it is applied to the package material.

The method according to the second embodiment comprises the steps of:
Providing a carrier substrate with at least two vias filled with an electrically conductive material, in particular a metal, through the carrier substrate;
Arranging at least one optoelectronic component on the carrier substrate, wherein the at least one optoelectronic component is configured to generate light in an ultraviolet range of the spectrum, and wherein the at least one optoelectronic component comprises at least two connection regions which point in the direction of the carrier substrate;
Attaching the at least one optoelectronic component to the carrier substrate in such a way that each of the connection regions is electrically coupled to one of the two electrically conductive vias;
Surrounding the at least one optoelectronic component arranged on the carrier substrate with a structured package material layer based on a fluoropolymer, in particular polytetrafluoroethylene, in such a way that the structured package material layer surrounds the at least one optoelectronic component arranged on the carrier substrate in the lateral direction.

In particular, the structured package material layer comprises at least one opening and is arranged on the carrier substrate in such a way that the at least one optoelectronic component is arranged in the at least one opening and thus the package material surrounds the at least one optoelectronic component arranged on the carrier substrate in the lateral direction.

The steps of providing the carrier substrate, arranging at least one optoelectronic component on the carrier substrate, and attaching the at least one optoelectronic component to the carrier substrate can correspond to the creation of a carrier composite of the at least one optoelectronic component on the carrier substrate, to which a prefabricated and pre-structured packaging material layer is applied, and thus the at least one optoelectronic component is surrounded by the packaging material.

According to at least one embodiment, the structured package material layer comprises a structured composite laminate layer comprising at least a first composite film and a first insulating layer based on a fluoropolymer, in particular comprising PTFE. Such a structured package material layer may, for example, be in the form of prefabricated PTFE laminates and thermoplastic composite films arranged therebetween, which comprise the at least one opening.

According to at least one embodiment, the method also comprises providing the structured package material layer comprising the steps of compression molding a package material in a mold tool and/or sintering the package material in a temperature range below 450° C. and in particular below 400° and in particular below 350° C. According to the principle of the method for producing a package, a pre-structured package material layer or a pre-structured fluoropolymer semi-finished product is thus produced in a first step.

According to at least one embodiment, the method further comprises pressing the carrier substrate with the package material layer and the at least one optoelectronic component. By pressing, in the case of a composite laminate layer, material of the composite film(s) can be pressed into gaps between the package material layer and the at least one optoelectronic component.

According to at least one embodiment, the method further comprises the step of removing excess package material from a top surface of the at least one optoelectronic component opposite the connection regions. This can ensure that there is no reflective material on the top surface of the at least one optoelectronic component and that the light emitted by the optoelectronic component can be coupled out of the optoelectronic package in the best possible way.

In a further aspect, the method comprises forming a transparent lens material on at least the top surface of the optoelectronic component. In particular, the lens material may protrude above an upper surface of the package material layer. The lens material can be formed in the desired manner so that additional collimation, focusing or scattering is possible.

According to at least one embodiment, the step of providing the carrier substrate comprises providing a PCB comprising at least a first structured copper laminate layer, a second structured copper laminate layer and an insulating layer disposed between the first structured copper laminate layer and the second structured copper laminate layer. The insulating layer comprises at least one of PTFE, FR4, and a mixture of PTFE and SiO2 particles.

Advantages resulting for an optoelectronic package described herein or for an optoelectronic package manufactured by means of the methods described herein may be as follows:
small component size, as the reflective layer in the form of the package material based on a fluoropolymer simultaneously forms a housing encapsulation for the optoelectronic component, thus eliminating the need for a separate housing encapsulation;
inexpensive components due to the reduced component size; and the use of a multi-layer stack as a carrier substrate, for example, enables simple yet complex control;
maximum usability of the light emitted by the optoelectronic component, especially in applications with secondary optics, as the light emitted by the optoelectronic component is also reflected directly on its side surfaces in the case of a volume emitter (surface emitter characteristic);
depending on the process flow variant, no solder or sinter interconnect is required between the carrier substrate and the optoelectronic component. This in turn leads to a reduction in costs, greater robustness and therefore less component damage, and improved moisture stability;
high robustness of the overall component, as there are only highly UVC-stable materials in the beam path of the light emitted by the optoelectronic component;
inexpensive components as inexpensive materials can be used for the carrier substrate;

### BRIEF DESCRIPTION OF THE DRAWINGS

Further aspects and embodiments according to the proposed principle will become apparent with reference to the various embodiments and examples described in detail in connection with the accompanying drawings.

FIGS. 1A to 3C show process steps of a process for manufacturing an optoelectronic package having some aspects according to the proposed principle;

FIGS. 4A and 4B show embodiments of an optoelectronic package with some aspects according to the proposed principle;

FIGS. 5A to 5E show process steps of a further process for manufacturing an optoelectronic package with some aspects according to the proposed principle;

FIGS. 6A to 8B show further embodiments of an optoelectronic package with some aspects according to the proposed principle;

FIGS. 9A to 9F show process steps of another process for manufacturing an optoelectronic package having some aspects according to the proposed principle; and

FIGS. 10A to 11B show further embodiments of an optoelectronic package with some aspects according to the proposed principle.

### DETAILED DESCRIPTION OF ILLUSTRATIVE EMBODIMENTS

The following embodiments and examples show various aspects and their combinations according to the proposed principle. The embodiments and examples are not always to scale. Likewise, various elements may be shown enlarged or reduced in size in order to emphasize individual aspects. It is understood that the individual aspects and features of the embodiments and examples shown in the figures can be readily combined with each other without affecting the principle of the invention. Some aspects comprise a regular structure or shape. It should be noted that slight deviations from the ideal shape may occur in practice without, however, contradicting the inventive concept.

In addition, the individual figures, features and aspects are not necessarily shown in the correct size, and the proportions between the individual elements are not necessarily correct. Some aspects and features are emphasized by enlarging them. However, terms such as “above”, “above”, “below”, “below”, “larger”, “smaller” and the like are shown correctly in relation to the elements in the figures. It is thus possible to deduce such relationships between the elements on the basis of the figures.

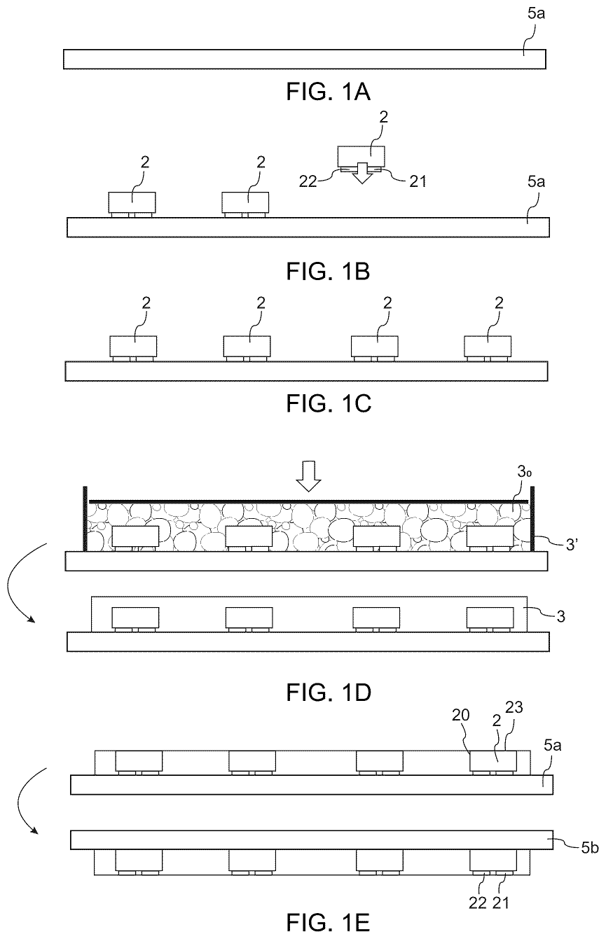

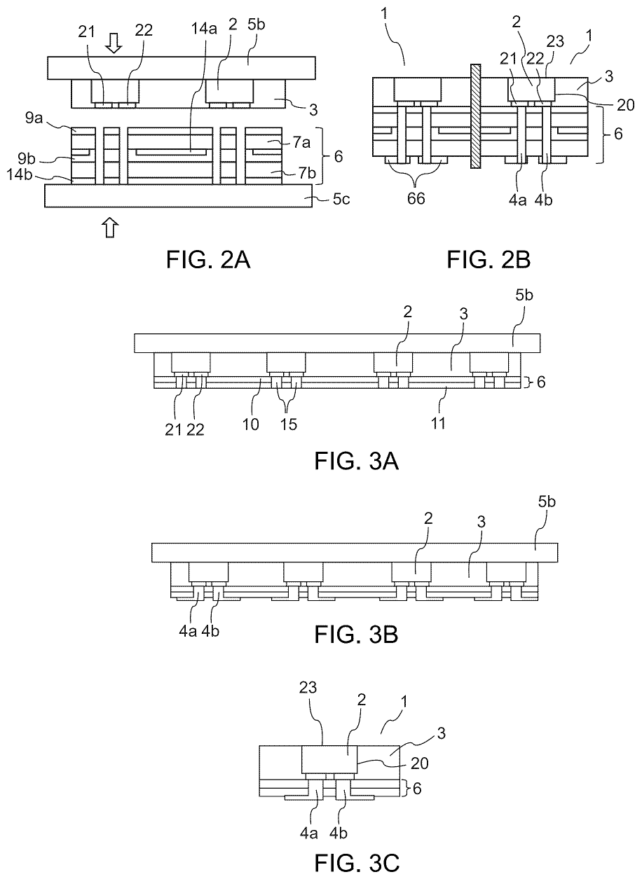

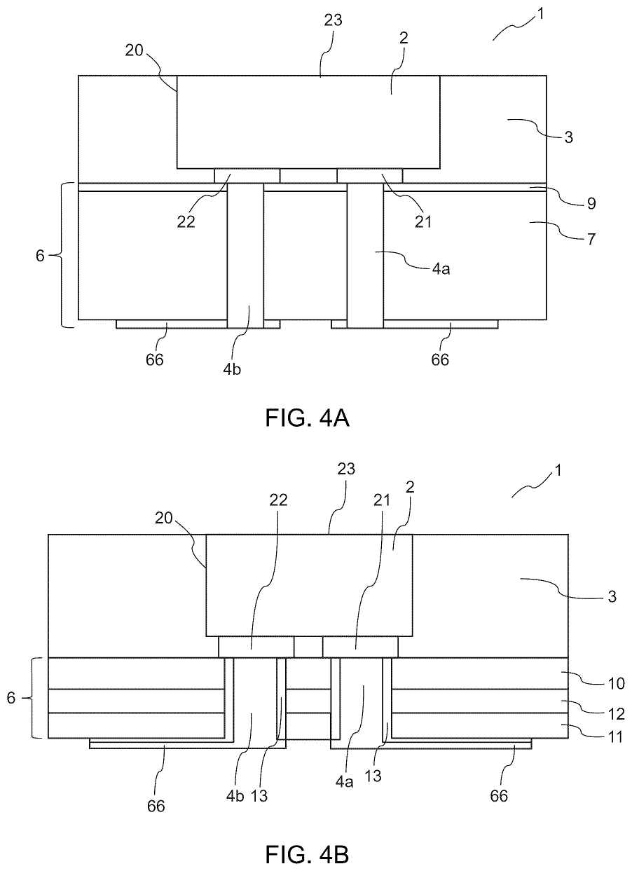

FIGS. 1A to 1E schematically show first process steps of an embodiment of a manufacturing process for an optoelectronic package according to the proposed principle. FIGS. 2A and 2B also show subsequent process steps of a first embodiment of the manufacturing method and FIGS. 3A to 3C show subsequent process steps of a second embodiment of the manufacturing method.

In FIG. 1A, a first temporary carrier 5a is provided, which in the present example has adhesive properties, in particular on a top surface thereof, in order to be able to place optoelectronic components on it and to fasten them at least temporarily. This step is shown in FIG. 1B, according to which, by way of example, three optoelectronic components 2 are placed on the temporary carrier 5a in such a way that electrical connection regions 21, 22 of the optoelectronic components 2 point in the direction of the temporary carrier 5a. FIG. 1C shows a temporary carrier 5a to which four optoelectronic components 2 comprise been attached as an example. The optoelectronic components 2 each comprise two electrical connection regions 21, 22, which are in contact with the first temporary carrier 5a. In this embodiment, only four optoelectronic components 2 are shown on the first temporary carrier 5a for producing at least one optoelectronic package, but it is understood that the first temporary carrier 5a can be designed as an endless strip and a plurality of optoelectronic components 2 can be arranged on the same.

The first temporary carrier 5a with the optoelectronic components 2 arranged on it is placed in a mold tool 3′ in a further step, shown in FIG. 1D. This comprises a lateral boundary and is placed on the temporary carrier in such a way that a space is created between the temporary carrier and the mold tool 3′, in which the optoelectronic components 2 are arranged. A powdery package material 30 based on a fluoropolymer is introduced into the intermediate space in the mold tool 3′ so that it completely surrounds the optoelectronic components 2. This is followed by compression molding under pressure and also at an elevated temperature (in the form of compression molding), during which the fluoropolymer bonds mechanically with the surface of the optoelectronic components 2.

The molded body produced in this way by compression molding can also be sintered so that the package material bonds with the optoelectronic components 2 in a mechanically stable manner. In this way, a mechanically stable and coherent fluoropolymer reflector is formed around the optoelectronic components 2. The sintering step can also take place during compression molding, so that pressure and increased temperature create the mechanical bond and stability.

During the compression step, however, package material often gets onto the top surface 23 of the optoelectronic components 2. Therefore, in a subsequent step, shown in FIG. 1E, a so-called deflashing (grinding back) takes place, in which residues of the package material on the top surface 23 are removed. For this purpose, the top surface of the optoelectronic components 2 is cleaned mechanically or chemically and mechanically.

Once the top surface 23 of the optoelectronic components 2 has been cleaned, a relamination step is carried out so that the connection regions 21, 22 in contact with the first temporary carrier 5a are exposed and can be addressed for further process steps. For this purpose, a second temporary carrier 5b is applied to the top surface 23 of the optoelectronic components 2 and the first temporary carrier 5a is removed.

FIGS. 2A and 2B show process steps of a first embodiment of the manufacturing process following on from those in FIGS. 1A to 1E. According to FIG. 2A, a previously produced carrier substrate 6, in the case shown in the form of a multilayer stack, is pressed with the package material & optoelectronic component composite. The carrier substrate 6 comprises thermoplastic composite films 9a, 9b, insulating layers 7a, 7b and structured copper laminate layers 14a, 14b. In addition, the carrier substrate 6 comprises vias 4a, 4b filled with an electrically conductive material, in particular a metal, which extend through the carrier substrate 6 and which are each coupled to one of the electrical connection regions 21, 22. The vias 4a, 4b can already be inserted in the multilayer stack or alternatively be created after pressing by laser and subsequent filling.

In a further step as shown in FIG. 2B, the first and second temporary carriers 5a, 5b are removed and a backside contact 66 is created for the optoelectronic packages 1 that are subsequently separated. This can be done using conventional PCB processes, such as metallization of the through-hole plating 4a, 4b. This is followed by a separation step shown by the hatched line, for example by sawing, which provides individual optoelectronic packages 1.

FIGS. 3A, 3B and 3C show process steps of a second embodiment of the manufacturing process following on from those in FIGS. 1A to 1E. According to FIG. 3A, a carrier substrate 6 in the form of several functional layers can also be applied directly to the package material 3 or the electrical connection regions 21, 22, for example by vapor deposition or sputtering. In a first step, as shown as an example in FIG. 3A, an insulating layer 10 (e.g. SiO₂, AlO₂₃) that is transparent to UV light is applied to the package material 3. The electrical connection regions 21, 22 are protected by an intermediate material 15, for example a lithographically produced lacquer layer. In a further step, a UV light-reflecting layer 11 is applied to the transparent layer 10, which is configured in particular to reflect light in the UVC wavelength range. This can be realized by a metallic layer (e.g. Al, Ag) or a combination of metallic mirror and Bragg reflector (DBR stack). Certain areas of this layer are also cut out and filled with the intermediate material 15, e.g. to ensure the electrical function of the LED chip or to create and fill vias 4a, 4b in a subsequent step, shown in FIG. 3B.

To create the vias 4a, 4b, the intermediate material is first removed and the resulting vias 4a, 4b are filled with an electrically conductive material. A backside contact 66 is then created for the optoelectronic packages 1 that are subsequently separated. This can be done using conventional PCB processes, such as metallization of the through-hole plating 4a, 4b. The vias 4a, 4b can be laterally enlarged and brought to an appropriate thickness (e.g. electroplating+plating, e.g. Cu, Au, Ni, Pt).

Finally, optoelectronic packages 1 are separated by a sawing process and removed from the second temporary carrier 5b. A correspondingly produced optoelectronic package 1 is shown in FIG. 3C.

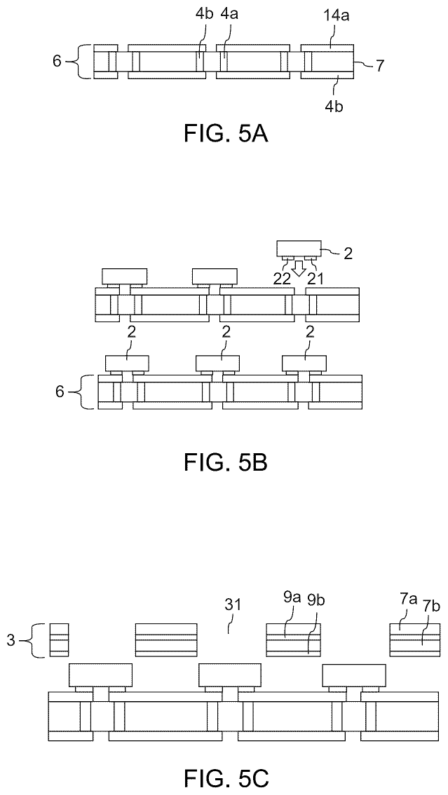

FIGS. 4A and 4B each show an illustration of an optoelectronic package 1 according to the proposed principle. According to the side view in FIG. 4A, the package 1 comprises a carrier substrate 6 with an insulating layer 7 and a composite film 9. In addition, the optoelectronic package 1 comprises an optoelectronic component 2 with a first and a second electrical connection region 21, 22, which is enclosed in a package material 3. The package material 3 consists of a fluoropolymer, for example tetrafluoropolyethylene. The optoelectronic component 2 is embedded or arranged in the package material 3 in such a way that side surfaces 20 and at least partially a lower side of the optoelectronic component 2 are covered by the package material 3, but a top surface 23 of the optoelectronic component 2 remains uncovered by the package material 3. The top surface 23 of the optoelectronic component is flush with the corresponding top surface of the package material 3. The two electrical connection regions 21, 22 are each coupled to a via 4a, 4b through the carrier substrate 6, and the optoelectronic component 2 is electrically controlled via the backside contacts 66, which are each electrically conductively connected to one of the vias 4a, 4b.

The fluoropolymer or package material 3 is used as a reflector for the optoelectronic package 1, and is arranged around the optoelectronic component 2 such that light emitted from the optoelectronic component 2 can emit substantially only through the top surface 23. By using a reflective corridor polymer, it is achieved that the light emitted by the optoelectronic component in the ultraviolet spectrum is reflected upwards by the side surfaces 20 and thus directed out of the top surface 23 or light emission plane. The use of a fluoropolymer also has the advantage that light in the ultraviolet range causes only minor ageing processes and thus significantly increases the service life of the package 1.

However, the carrier substrate 6 can also comprise other layers, as shown, for example, in FIG. 4B. Accordingly, the carrier substrate 6 comprises an insulating layer 10 that is transparent to UV light (e.g. SiO₂, Al₂O₃), a reinforcing layer 12 and a UV light-reflecting layer 11 (e.g. Al, Ag). The vias 4ₐ, 4_{b}, which are each electrically coupled to one of the two electrical connection regions 21, 22, extend through the carrier substrate 6. The vias 4a, 4b are also each protected by a passivation layer 13 surrounding the vias 4a, 4b in the lateral direction, so that they are not in contact with the layers of the carrier substrate. This can, for example, prevent a possible short circuit within the optoelectronic package 1. The backside contacts 66, which are each electrically conductively connected to one of the vias 4a, 4b, can be formed, for example, by a structured copper laminate layer or by an electroplated metallic material.

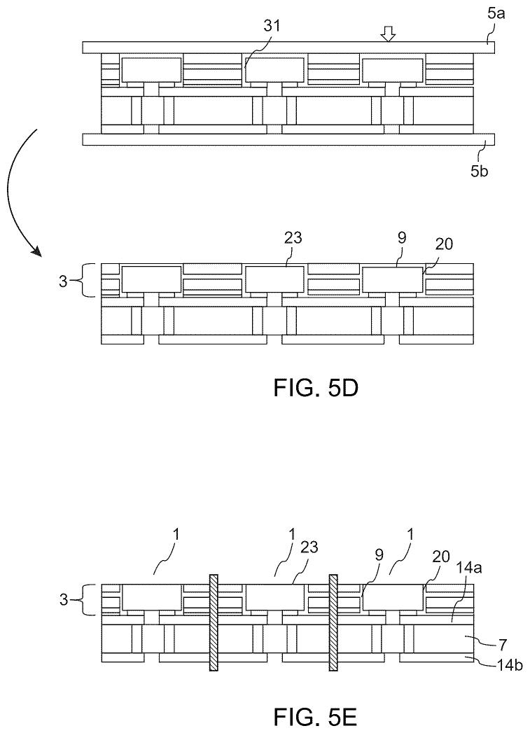

FIGS. 5A to 5E show process steps of a further process for manufacturing an optoelectronic package with some aspects according to the proposed principle. In FIG. 5A, a carrier substrate 6 is provided which is in the form of a copper laminate structure having an inner insulating core or layer 7. The copper laminate structure comprises a first structured copper laminate layer 14a and a second structured copper laminate layer 14b. The inner core 69 comprises tetrafluoropolyethylene or another suitable insulating material such as FR4 and comprises a plurality of vias 4a, 4b filled with an electrically conductive material. The vias 4a, 4b each connect regions of the structured first copper laminate layer 14a and the structured second copper laminate layer 14b.

In a subsequent step, optoelectronic components 2 are placed on the carrier substrate 6 or on the first structured copper laminate layer 14a, as shown in FIG. 5B, in such a way that electrical connection regions 21, 22 of the optoelectronic components 2 point in the direction of the carrier substrate 6 or the first structured copper laminate layer 14a. FIG. 5B shows in the lower partial image a carrier substrate 6 to which three optoelectronic components 2 have been applied as an example. The optoelectronic components 2 each comprise two electrical connection regions 21, 22, which are in contact with the first structured copper laminate layer 14a. In this embodiment, only three optoelectronic components 2 are shown on the carrier substrate 6 for producing at least one optoelectronic package, but it is understood that the carrier substrate 6 can be formed as an endless strip and a plurality of optoelectronic components 2 can be arranged on the same.

This embodiment has the advantage that the carrier substrate or the copper laminate structure 6 is already available as a prefabricated carrier substrate and the package material can be manufactured from the fluoropolymer and applied in a separate step. According to FIG. 5C, a package material 3 in the form of a composite laminate layer is applied to the carrier substrate 6 with the optoelectronic components 2 arranged thereon. The package material comprises a first composite film 9a arranged between a first and second insulating layer 7a, 7b and a second composite film 9b arranged on the second insulating layer 7b. The insulating layers 7a, 7b are based on a fluoropolymer, in particular comprising PTFE, and are arranged in the form of a stack of layers on top of one another with composite films in between. The second composite film 9b, which is arranged on the second insulating layer, is in contact with the carrier substrate 6. The composite films may, for example, be adhesive films, which may comprise at least one of CTFE and FEP.

The composite laminate layer 3 is pre-structured, i.e. comprises a structure or openings 31, and is arranged on the carrier substrate 6 in such a way that the optoelectronic components 2 are each arranged in one of the openings 31. The optoelectronic components 2 are accordingly each surrounded by the composite laminate layer 3, but at this point there may still be a gap between the optoelectronic components 2 and the composite laminate layer 3 in order to enable the composite laminate layer 3 to be arranged on the carrier substrate 6 without colliding with the optoelectronic components 2.

According to FIG. 5D, the composite laminate layer 3 is then pressed with the carrier substrate 6 or the optoelectronic components 2, whereby material of the first or second composite film 9a, 9b is pressed into the spaces between the optoelectronic components 2 and the composite laminate layer 3. As a result, the side surfaces 20 are covered by the package material 3 in the form of the material of the first or second composite film 9a, 9b. Since the second composite film 9b is also in contact with the carrier substrate 6, a good bond between the carrier substrate 6 and the package material 3 can be ensured after pressing.

As shown in the lower partial image of FIG. 5D, material of the composite film may also be present on the top surface 23 of the optoelectronic components 2 after pressing. This material is removed in a subsequent step, as shown in FIG. 5E, and the top surface 23 is cleaned before the optoelectronic packages 1 are produced by a separation step, for example by sawing.

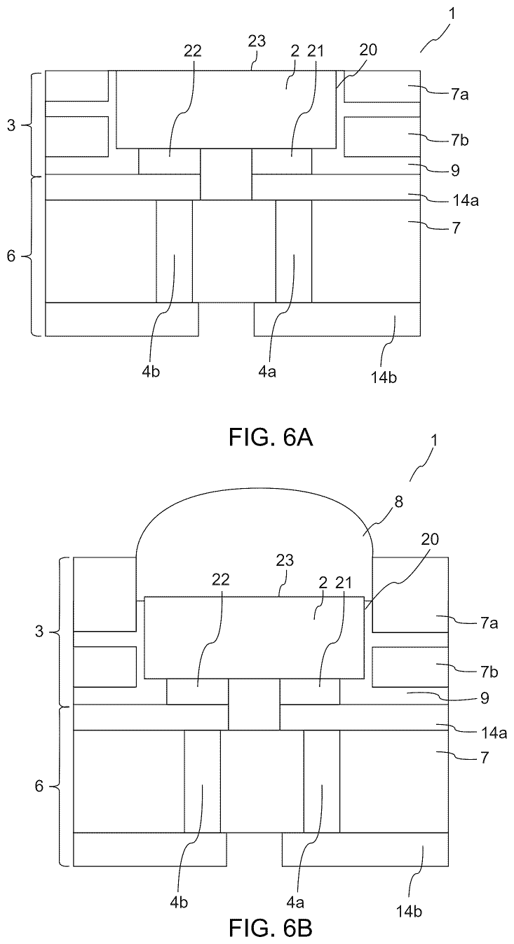

FIGS. 6A and 6B show possible embodiments of a correspondingly manufactured optoelectronic package 1. FIG. 6A shows once again that the top surface 23 of the optoelectronic component 2 is flush with the corresponding top surface of the package material 3, and that the side surfaces 20 of the optoelectronic component 2 are covered with the package material 3 in the form of the material of the composite foils 9. In addition, it can be seen that the vias 4a, 4b each connect areas of the structured first copper laminate layer 14a and the structured second copper laminate layer 14b, and that the electrical connection regions 21, 22 are each in contact with one of the areas of the first structured copper laminate layer 14a. The optoelectronic package 1 can be controlled accordingly via the regions of the structured second copper laminate layer 14b.

FIG. 6B shows an embodiment in which the optoelectronic package 1 also includes an additional material that forms a lens-shaped structure 8 above the light exit side or top surface 23 of the optoelectronic component 2. The shape of the lens can be selected as required so that the light emitted by the optoelectronic component 2 during operation is collimated and emitted upwards as a directed beam. Like the package material 3, the lens material 8 is resistant to the radiation generated by the component 2, so that the service life is not reduced as a result.

In addition, FIG. 6B shows that the top surface 23 of the optoelectronic component 2 is set back relative to the corresponding top surface of the package material 3, so that the component 2 is arranged completely within a recess in the package material 3. In addition, the side surfaces 20 of the optoelectronic component 2 are only partially covered by the material of the composite films 9, so that an anchoring structure is formed for the lens material in the space between the optoelectronic component 2 and the package material 3. The fact that the package material 3 only partially covers the side surfaces 20 can be adjusted, for example, by adjusting the thickness of the composite films 9 accordingly so that less material of the composite films 9 is available to be pressed into the interstices and/or by adjusting the manufacturing parameters during the pressing step, such as pressure and/or temperature. By adjusting the production parameters, for example, the viscosity of the material of the composite films 9 can be set, and depending on the pressing pressure, it is also possible to set how much material is pressed into the interstices depending on the viscosity of the material.

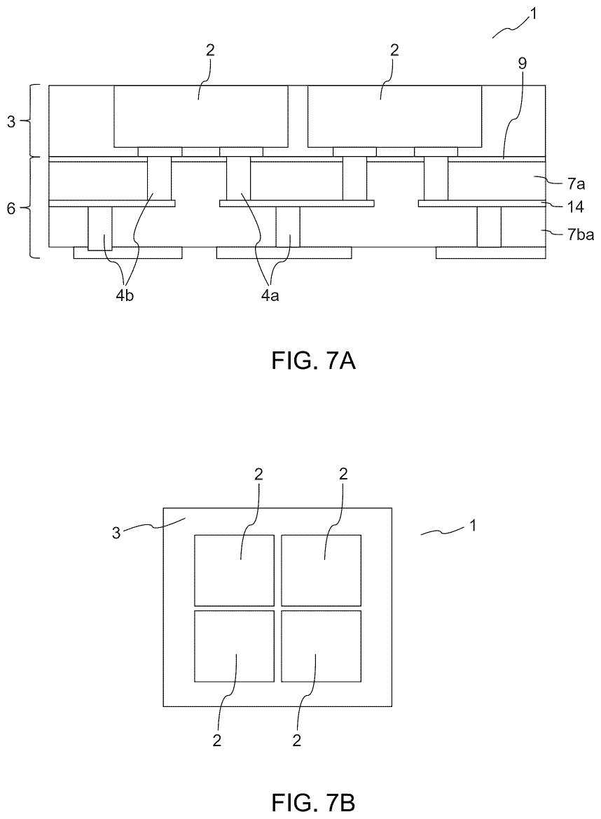

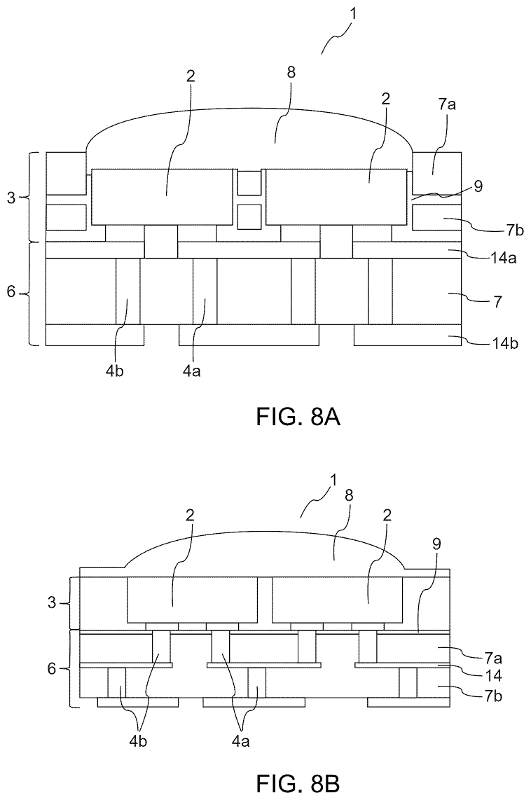

FIGS. 7A to 8B show further possible embodiments of a correspondingly manufactured optoelectronic package 1. The optoelectronic packages 1 shown in each case have two or four optoelectronic components 2, which are each arranged on the carrier substrate 6. The packages 1 can be so-called multi-chip packages. However, the number and arrangement of the optoelectronic components 2 shown should be understood as merely exemplary, and several optoelectronic components 2 can also be arranged on the carrier substrate 6 in any desired arrangement.

According to FIG. 7A, the carrier substrate 6 comprises a multi-stack structure with a first insulating layer 7a, a second insulating layer 7b, a composite foil 9 and a structured copper laminate layer 14. The vias 4a, 4b extend through the carrier substrate 6 or through the insulating layers 7a, 7b and connect the connection regions 21, 22 with areas of the structured copper laminate layer 14. Such a carrier substrate 6 can provide several interconnection levels and thus a more complex control of the optoelectronic components 2.

FIG. 7B shows a top view of an optoelectronic package 1 or multi-chip package. The optoelectronic components 2 are arranged axially symmetrically to each other in a square and are surrounded by the package material 3 or separated from each other in the lateral direction.

FIGS. 8A and 8B each show an embodiment of an optoelectronic package 1 or multi-chip package comprising an additional material which forms a lens-shaped structure 8 above the light exit side or top surface 23 of the optoelectronic components 2. The shape of the lens can be selected as required so that the light emitted by the optoelectronic components 2 during operation is collimated and emitted upwards as a directed beam. Like the package material 3, the lens material 8 is resistant to the radiation generated by the component 2, so that the service life is not reduced as a result.

According to FIG. 8A, the lens material 8 is arranged in a recess in the package material 3 on the top surface 23 of the optoelectronic components 2, whereas in the embodiment shown in FIG. 8B, the lens material 8 is arranged or formed on the top surface 23 of the optoelectronic components 2 or on the top surface of the package material 3 which is flush therewith.

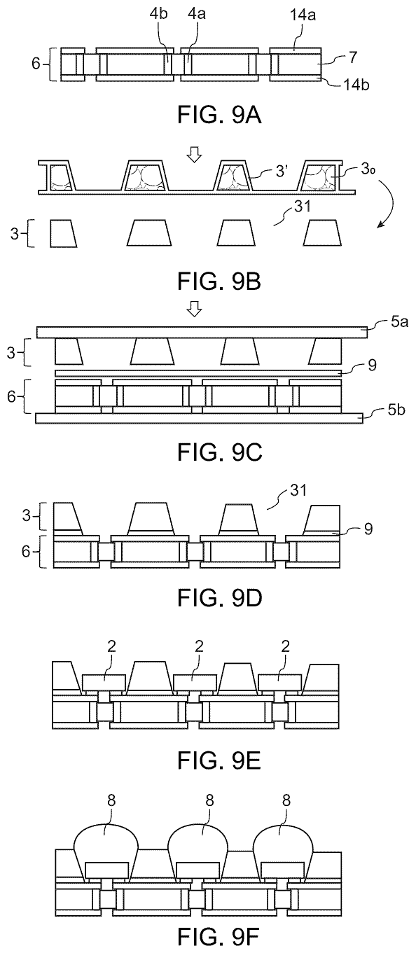

FIGS. 9A to 9F show a further embodiment of a manufacturing process for an optoelectronic package according to some aspects of the proposed principle. The starting point for this process is a separately produced package material layer/reflector 3 with openings 31 based on a floor polymer material and a carrier substrate 6 with a multi-stack structure, as is already known, for example, as a printed circuit board. These two elements are then connected by means of a thermoplastic composite film 9 that is stable against ultraviolet radiation. Films made of CTFE (chlorotrifluoroethylene) or FEP (tetrafluoroethylene-hexafluoropropylene copolymer) are possible options here.

FIG. 9A outlines the provision of the carrier substrate 6 as a copper laminate structure. This comprises a first structured copper laminate layer 14a, a second structured copper laminate layer 14b and an intermediate insulating layer 7, for example made of PTFE or FR4. The structured copper laminate layers 14a, 14b can be roughened, glued or otherwise bonded to the insulating layer 7. The first structured copper laminate layer 14a comprises regions that are designed to form contact surfaces for an optoelectronic component that is applied later, and the second structured copper laminate layer 14b comprises regions that serve as backside contacts for the optoelectronic package. The carrier substrate 6 further comprises various vias 4a, 4b which, as shown, each connect regions of the first structured copper laminate layer 14a to regions of the second structured copper laminate layer 14b. Such a structure can be produced as an endless strip and can be shortened to a desired length as required.

The package material 3 based on a fluoropolymer is prepared separately. For this purpose, the powdered material 30 based on a fluoropolymer is introduced into intermediate spaces in a mold tool using compression molding and pressed to form a semi-finished product and molded body. In addition, sintering takes place in a second step so that the package material layer 3 with the openings 31 shown in FIG. 9B is formed. Unlike most thermoplastics, the packaging material does not have a melting point, i.e. it decomposes directly at high temperatures without first becoming liquid. Although this prevents production by injection molding, it allows the temperature steps associated with the sintering process to be separated from the later process steps and the package material to be produced separately.

In a subsequent step in FIG. 9C, an adhesive composite film 9 is applied to the carrier substrate 6. This additional composite film 9 is used to subsequently attach the package material layer 3 to the carrier substrate 6. For this purpose, the package material layer is attached to a first temporary carrier 5a and this is then bonded to the composite film 9. An additional temperature step or pressing step may be necessary to form an intimate bond between the composite film 9 on one side and the carrier substrate 6 as well as the package material layer 3 on the other side.

The temporary carrier 5a is then removed as shown in FIG. 9D and components of the composite film 9 are removed from contact areas of the carrier substrate 6 as shown in FIG. 9D. In a subsequent step, optoelectronic components 2 are placed in the openings 31 on the contact areas of the first structured copper laminate layer 14a that are thus exposed, as shown in FIG. 9E. In a further optional step, the exposed contact surfaces can additionally be pre-processed in order to achieve a better electrical and mechanical connection to the connection regions 21, 22 of the components 2. In the present embodiment example, the components 2 comprise a corresponding solder on their connection regions 21, 22, so that an additional step of applying a material to the contact areas of the carrier substrate 6 is not necessary.

In a final optional step, the openings can be filled with an additional transparent material and shaped into a lens. On the one hand, this protects the optoelectronic components 2 and, on the other hand, the lens shape allows the light emitted by the components to be collimated or shaped.

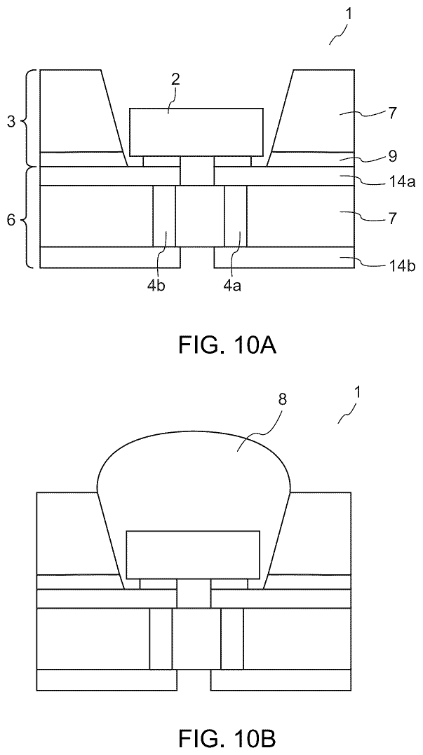

FIGS. 10A and 10B show embodiments of an optoelectronic package 1 produced and separated in this way. FIG. 10A shows an optoelectronic package 1 which has been produced by separating the structure shown in FIG. 9E, and FIG. 10B shows an optoelectronic package 1 which has been produced by separating the structure shown in FIG. 9F.

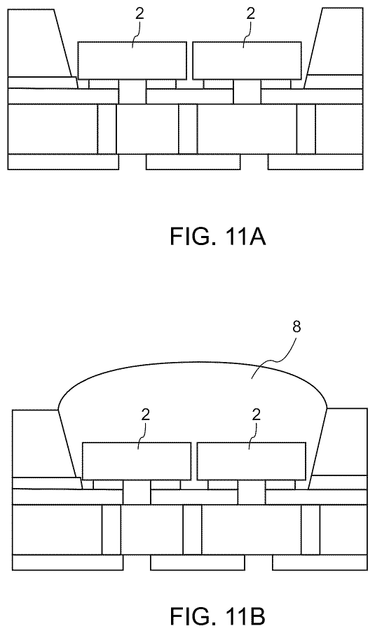

Similarly, FIGS. 11A and 11B also show a corresponding embodiment example in which the carrier substrate 6 is designed as a structured copper laminate with an inner core based on TFPE or FR4, as in the embodiment examples of FIGS. 10A and 10B. The package material layer is applied to a composite film 9 and attached to it. Contrary to the embodiments of FIGS. 10A and 10B, however, two optoelectronic components 2 are arranged in the opening 31, so that the packages are so-called multi-chip packages. One of the vias or an area of the first and second structured copper laminate layers, which are connected by means of the vias, act as a common electrical connection for the two optoelectronic components 2. According to FIG. 11B, a transparent material 8 is introduced into the opening, which forms a light-forming element for both optoelectronic components 2.

In the principle proposed here, a pre-structured package material layer based on a fluoropolymer material is formed, which serves as a reflector for a package in subsequent process steps. The separate production makes it possible to optimize the necessary process parameters for producing the package material layer from the fluoropolymer. This prevents possible damage to an optoelectronic component due to excessive temperatures or mechanical stress, which would occur during joint production due to the process parameters required to produce the package material layer.

To improve the adhesion of the material of the package material layer to the carrier substrate or to another surface, it is possible to roughen the carrier substrate with additional process steps, such as plasma etching, to achieve a better mechanical bond. A package material layer produced in this way serves as a reflector and can be provided with additional light-shaping elements. Since fluoropolymer is largely reflective for light in the ultraviolet range and at the same time shows a high resistance to this radiation, it is particularly suitable for the design of packages for ultraviolet light. The use of a composite laminate layer and subsequent pressing allows the package material used to be coupled to the carrier substrate with sufficient stability and strength.

The process results in a semi-finished product in which the high-temperature steps, in particular the sintering process and compression molding process, have already been carried out before the optoelectronic component is applied.

1.-28. (canceled)

29. An optoelectronic package comprising:
a carrier substrate comprising at least two through vias filled with an electrically conductive material;
at least one optoelectronic component arranged on the carrier substrate, wherein the at least one optoelectronic component is configured to generate light in an ultraviolet range, and wherein the at least one optoelectronic component has at least two connection regions, each of which is electrically coupled to one of the two electrically conductive vias; and
a package material surrounding the at least one optoelectronic component, wherein the package material is based on a fluoropolymer and covers side surfaces of the at least one optoelectronic component at least in regions, and wherein a top surface of the at least one optoelectronic component opposite the connection regions remains free of the package material.

30. The optoelectronic package according to claim 29, wherein the top surface of the at least one optoelectronic component is substantially flush with the package material.

31. The optoelectronic package according to claim 29, further comprising a transparent lens material arranged on the top surface of the at least one optoelectronic component.

32. The optoelectronic package according to claim 29, wherein the package material comprises a composite laminate layer.

33. The optoelectronic package according to claim 32, wherein the package material comprises at least one first composite film and a first insulating layer based on the fluoropolymer.

34. The optoelectronic package according to claim 33, wherein the at least one first composite film or a material of the at least one first composite film covers the side surfaces of the at least one optoelectronic component at least in regions.

35. The optoelectronic package according to claim 29, wherein the package material is sintered on basis of the fluoropolymer.

36. The optoelectronic package according to claim 29, wherein the carrier substrate comprises an UV light transparent insulating layer being at least partially transparent to UV light and a UV light reflecting layer.

37. The optoelectronic package according to claim 36, wherein the UV light transparent insulating layer is in contact with the package material.

38. The optoelectronic package according to claim 36, wherein the carrier substrate further comprises a reinforcing layer between the UV light transparent insulating layer and the UV light reflecting layer.

39. The optoelectronic package according to claim 36, wherein the UV light reflecting layer comprises an electrically conductive material.

40. The optoelectronic package according to claim 29, wherein the carrier substrate comprises a multilayer stack having at least a first composite film, a first structured copper laminate layer and a first insulating layer arranged between the first composite film and the first structured copper laminate layer.

41. The optoelectronic package according to claim 40, wherein the first composite film is formed by a thermoplastic composite film and is in contact with the package material.

42. The optoelectronic package according to claim 41, wherein the first composite film comprises at least one of the following materials:
CTFE,
FEP, or
a fluoropolymer.

43. The optoelectronic package according to claim 40, wherein the multilayer stack further comprises a second insulating layer and a second composite film arranged between the two insulating layers.

44. The optoelectronic package according to claim 29, wherein the carrier substrate comprises a multilayer stack having at least a first structured copper laminate layer, a second structured copper laminate layer and a first insulating layer arranged between the first structured copper laminate layer and the second structured copper laminate layer.

45. The optoelectronic package according to claim 44, wherein the first insulating layer comprises at least one of the following materials:
PTFE,
FR4,
a fluoropolymer, or
a mixture of PTFE and SiO2 particles.

46. A method for manufacturing at least one optoelectronic package, the method comprising:
providing a first temporary carrier with at least one optoelectronic component arranged thereon, wherein the at least one optoelectronic component is configured to generate light in an ultraviolet range and comprises at least two connection regions facing in a direction of the first temporary carrier;
inserting the first temporary carrier into a mold tool;
surrounding the at least one optoelectronic component arranged on the first temporary carrier with a package material based on a fluoropolymer such that at least some side surfaces of the optoelectronic component are covered by the package material and a top surface of the at least one optoelectronic component opposite the connection regions remains free of the package material;
removing the first temporary carrier; and
providing a carrier substrate with at least two through vias filled with an electrically conductive material on a side of the package material opposite the top surface of the at least one optoelectronic component, wherein each of the two electrically conductive vias is electrically coupled to one of the connection regions.

47. The method according to claim 46, wherein the mold tool is configured for compression molding.

48. The method according to claim 46, wherein surrounding the at least one optoelectronic component comprises:
compression molding the package material into a gap surrounding the at least one optoelectronic component arranged on the first temporary carrier, and/or
sintering the package material arranged in the gap in a temperature range below 450° C.

49. The method according to claim 46, further comprising pressing the carrier substrate with the package material and the at least one optoelectronic component.

50. The method according to claim 46, wherein providing the carrier substrate comprises creating and filling the at least two vias after the carrier substrate has been arranged on the side of the package material opposite to the top surface of the at least one optoelectronic component.

51. A method for manufacturing at least one optoelectronic package, the method:
providing a carrier substrate comprising at least two through vias through filled with an electrically conductive material;
arranging at least one optoelectronic component on the carrier substrate, wherein the at least one optoelectronic component is configured to generate light in an ultraviolet range, and wherein the at least one optoelectronic component comprises at least two connection regions facing in a direction of the carrier substrate;
attaching the at least one optoelectronic component to the carrier substrate such that each of the connection regions is electrically coupled to one of the two electrically conductive vias; and
surrounding the at least one optoelectronic component arranged on the carrier substrate with a structured package material layer based on a fluoropolymer such that the structured package material layer surrounds the at least one optoelectronic component arranged on the carrier substrate in a lateral direction, wherein the structured package material layer comprises a structured composite laminate layer with at least a first composite film and a first insulating layer based on the fluoropolymer.

52. The method according to claim 51, further comprising providing the structured package material layer by:
compression molding a package material in a mold tool, and/or
sintering the package material in a temperature range below 450° C.

53. The method according to claim 52, further comprising pressing the carrier substrate with the package material layer and the at least one optoelectronic component.

54. The method according to claim 52, further comprising removing the package material on a top surface of the at least one optoelectronic component opposite the connection regions.

55. The method according to claim 51, further comprising molding a transparent lens material on a top surface of the at least one optoelectronic component.

56. The method according to claim 51, wherein providing the carrier substrate comprises providing a PCB comprising at least a first structured copper laminate layer, a second structured copper laminate layer and a first insulating layer arranged between the first structured copper laminate layer and the second structured copper laminate layer, and wherein the first insulating layer comprises at least one of the following materials:
PTFE,
FR4,
a fluoropolymer, or
a mixture of PTFE and SiO2 particles.
